(19) United States
(12) Patent Application Publication
(10) Pub. No.: US 2011/0025922 A1
(43) Pub. Date: Feb. 3, 2011

(54) DISPLAY DEVICE AND FRAME BODY FOR DISPLAY DEVICE

(76) Inventor: Noriaki Toya, Fukaya-shi (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/778,778

(22) Filed: May 12, 2010

(30) Foreign Application Priority Data
Jul. 31, 2009 (JP) 2009-179525

(51) Int. Cl. H04N 5/50; H05K 7/00; A47B 81/06

(52) U.S. Cl. 348/731; 361/829; 312/7.2; 348/E05.097

(57) ABSTRACT

According to one embodiment, a front panel that surrounds a display unit incorporated in a display device, such as a TV set, for displaying images is formed by securing a plastic frame to a metal frame. Notches provided between screw holes as fixing portions of the plastic frame and the metal frame absorb thermal deformation of the plastic frame due to a change in temperature, thereby realizing a display device and a TV set with displacement of the plastic frame and the metal frame due to the thermal deformation reduced.

### CROSS-REFERENCE TO RELATED APPLICATIONS

This application is based upon and claims the benefit of priority from Japanese Patent Application No. 2009-179525, filed Jul. 31, 2009, the entire contents of which are incorporated herein by reference.

### FIELD

Embodiments described herein relate generally to a display device and a frame body for the display device, and more particularly to a display device and a frame body for the display device, which can absorb thermal deformation of the housing of the device.

### BACKGROUND

In each of various devices, members of different materials are often used. If the members have different thermal expansion coefficients, unexpected thermal deformation is liable to occur because of changes in ambient temperature or the temperature of the device itself. Jpn. Pat. Appln. KOKAI Publication No. 2003-248185 has proposed an operational optical device and an image forming device, in which a notch is formed in a fixing member for fixing members of high thermal expansion coefficients, to absorb thermally expanded portions of the members and to reliably fix the expanded members, thereby solving the problem of thermal deformation of the members due to changes in temperature.

In, for example, display devices, the environment may differ between the time of manufacturing and the time of use, and changes in temperature may adversely affect the members of the display devices. For instance, assume here that a frame body is formed by attaching members that are formed of different materials and have different thermal coefficients. In this case, if the frame body is manufactured and used at different temperatures, shear or warpage may well occur, resulting in deformation of the frame body. In addition, since the display device houses a large number of electronic components, temperature changes will further easily occur due to the heat generated by the components.

### BRIEF DESCRIPTION OF THE DRAWINGS

FIG. 1 is an exemplary perspective view illustrating the outline of an example of a TV set according to an embodiment;

FIG. 2 is an exemplary exploded perspective view illustrating examples of a display panel and a housing according to the embodiment;

FIG. 3 is an exemplary perspective view illustrating the outline of an example of a front panel according to the embodiment;

FIG. 4 is an exemplary view useful in explaining an example of a method employed in the embodiment for connecting a plastic frame to a metal frame;

FIG. 5 is an exemplary enlarged view illustrating a part of FIG. 4; and

FIG. 6 is an exemplary view useful in explaining an example of a method for connecting a plastic frame to a metal frame.

### DETAILED DESCRIPTION

In general, according to one embodiment, a front panel that surrounds a display unit incorporated in a display device, such as a TV set, for displaying images is formed by securing a plastic frame to a metal frame. Notches provided between screw holes as fixing portions of the plastic frame and the metal frame absorb thermal deformation of the plastic frame due to a change in temperature, thereby realizing a display device and a TV set with displacement of the plastic frame and the metal frame due to the thermal deformation reduced.

An embodiment will be described with reference to the accompanying drawings.

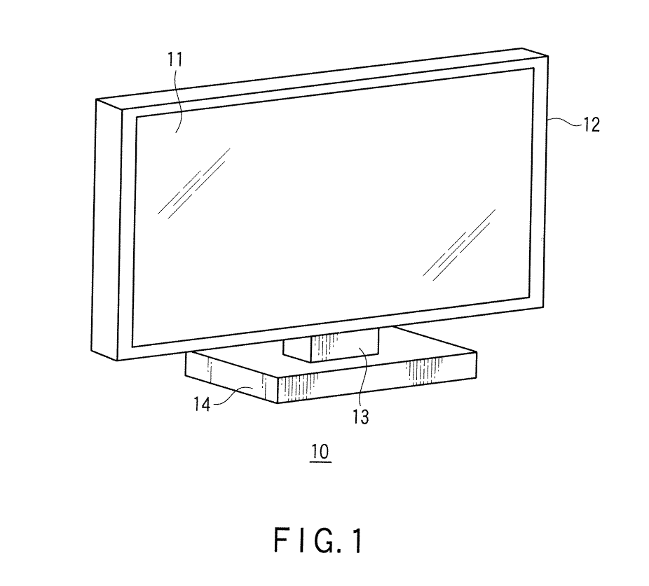

FIG. 1 shows the outline of an example of a TV set according to the embodiment. As shown, the TV set 10 comprises a display panel 11, a housing 12, a support neck portion 13 and a support seat 14.

The TV set 10 is a display device for receiving broadcast waves generated by a broadcast station, using a tuner (not shown), acquiring image information from the received broadcast waves, and outputting the image information for a user. Although the TV set 10 is illustrated as an example of the display device, the embodiment is not limited to this. Various display devices, such as a personal computer (PC), can be employed in place of the TV set 10.

The display panel 11 is a display unit for displaying the image information. In the embodiment, the display panel 11 is a panel for an LCD. However, this is merely an example, and the embodiment is not limited to it, and various panels, such as a plasma display panel (PDP), a cathode ray tube (CRT), and an organic electro-luminescence (EL) panel, can also be used.

The housing 12 is a box-shaped cover for protecting the internal modules of the TV set 10, and has an opening at the front side of the TV set 10 (at the side a user sees TV programs). The display panel 11 is exposed to the outside through the opening of the housing 12 so that the user can see the TV programs. Thus, the display panel 11 outputs image information to the user from the portion thereof exposed through the opening of the housing 12.

The support neck portion 13 supports from below the housing 12 and the internal modules housed in the housing 12. In the embodiment, the support neck portion 13 is in a shape of a rectangular parallelepiped. However, the invention is not limited to it, and various shapes, such as a cylinder, may be employed. It is sufficient if the housing 12 and the internal modules housed therein can be supported.

The support seat 14 is brought into contact with a flat surface on which the TV set 10 is installed, and supports the entire TV set 10. Like the support neck portion 13, the support seat 14 is not limited to the shape shown in FIG. 1, but may have any appropriate shape.

Further, although in the TV set 10 of the embodiment, the support neck portion 13 and the support seat 14 are formed separate from each other, they may be formed integral as one body.

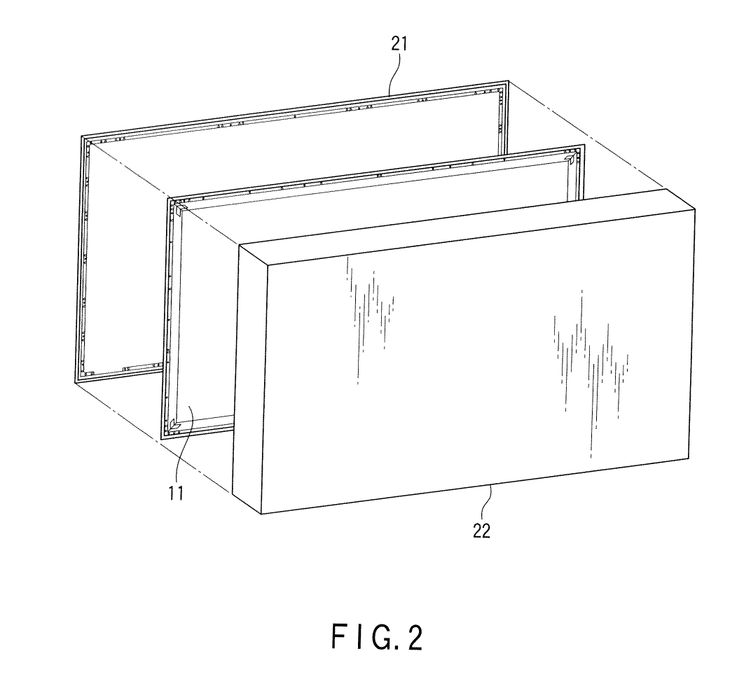

FIG. 2 is an exploded perspective view illustrating examples of the display panel 11 and the housing 12 according to the embodiment. More specifically, FIG. 2 shows a front-side panel 21, the display panel 11 and a rear-side housing 22.

The front-side panel 21 is a part of the front side (through which the display panel 11 is exposed) of the housing 12. The front-side panel 21 has an opening that enables the display panel 11 for displaying video images to be seen from the front, and is in a frame shape for fixing the periphery of the display panel 11.

The rear-side housing 22 is part of the rear side portion (through which the display panel 11 is not exposed) of the housing 12. The rear-side housing 22 covers the portions of the display panel 11 other than the front side of the panel, and houses various internal modules of the TV set 10 including a tuner.

The members shown in FIG. 2 are arranged in the order of the front-side panel 21, the display panel 11 and the rear-side housing 22, from the front (i.e., from the user side). The housing 12 comprises the front-side panel 21 and the rear-side housing 22. When the front-side panel 21 and the rear-side housing 22 are attached, the display panel 11 is housed in the housing 12, so that it outputs image information through the opening of the front-side panel 21.

The front-side panel 21 and the display panel 11 are attached to each other by screws. Screw holes are formed in the portions of the display panel 11 near the edges thereof. Further, screw holes are formed in the portions of the front-side panel 21 corresponding to the screw holes of the display panel 11 (i.e., the screw holes of the front-side panel 21 and the display panel 11 are superposed when the panels are attached). The front-side panel 21 and the display panel 11 are attached to each other by the screws inserted through the screw holes.

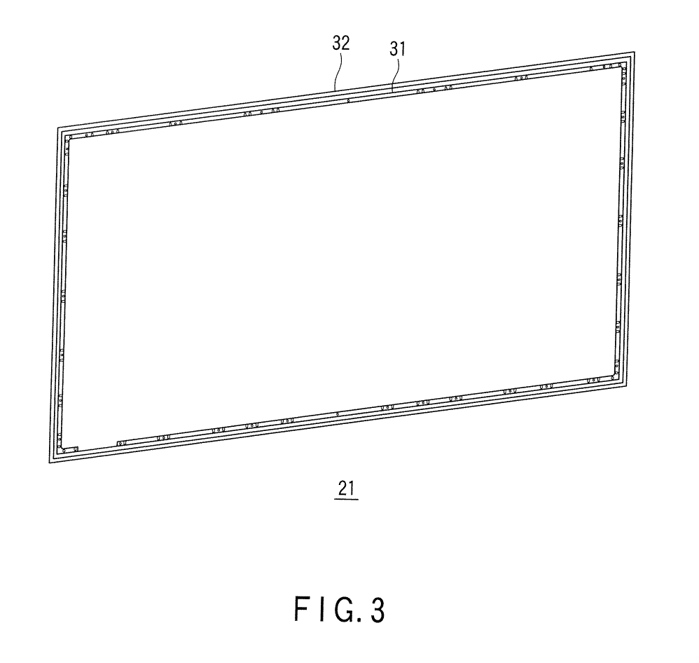

FIG. 3 is a perspective view illustrating the outline of an example of the front panel 21 according to the embodiment. Specifically, FIG. 3 shows the front panel 21, a plastic frame 31 and a metal frame 32. In FIG. 3, the rear side of the front panel 21 is shown as in the case of FIG. 2.

In the embodiment, the plastic frame 31 is a frame-shaped member (frame body) formed of plastic. Since the plastic frame 31 has a coefficient of thermal expansion several times that of the metal frame 32, a great difference will occur in the degree of deformation between these frames in accordance with a change in temperature. Although in the embodiment, the material of the plastic frame 31 is not limited to plastic, but may be other materials (including rubber) that have coefficients of thermal expansion different from that of the metal frame 32.

The metal frame 32 is a frame-shaped member (frame body) having substantially the same shape. The metal frame 32 is formed of a metal having a coefficient of thermal expansion that differs from the thermal expansion coefficient of the plastic frame 31. Although the embodiment uses a metal (such as aluminum) as the material of the metal frame 32, the embodiment is not limited to this. This frame may be formed of another material. It is sufficient if the material of the frame 32 has a lower coefficient of thermal expansion than that of the plastic frame 31.

The front panel 21 is formed of two members, i.e., the plastic frame 31 and the metal frame 32. The plastic frame 31 and the metal frame 32 have respective screw holes formed in corresponding portions, and are fixed to each other by screws inserted through the screw holes. The front panel 21 is formed by sticking, to each other, the two frame bodies, i.e., the plastic frame 31 and the metal frame 32, to superpose them on each other. Since in the embodiment, the plastic frame 31 and the metal frame 32 have significantly different coefficients of thermal expansion, the plastic frame 31 is deformed more greatly than the metal frame 32 when there is a change in temperature. Accordingly, even when the plastic frame 31 and the metal frame 32 are fixed to each other by, for example, screws, the portions of the plastic frame 31 other than the fixed portions may well be greatly deformed, thereby causing displacements or warpage in which, for example, the plastic frame 31 squeezes out the metal frame 32. The change in temperature may be caused by, for example, a change in external environment, heat generation of the internal electronic devices, or heat generation of the display panel 11. When the display panel 11 generates heat, it significantly affects the front panel 21 because they are located close to each other.

Although in the embodiment, the plastic frame 31 and the metal frame 32 are directly fixed to each other, the invention is not limited to this. A certain member may be interposed between them.

In the embodiment, the front panel 21 is formed of different members as shown in FIG. 3. This is more advantageous to the case where the front panel is formed of a single member, since the former case has a higher degree of freedom in design than the latter case, and hence can satisfy aesthetic purposes for enhancing consumers' buying motivation.

Furthermore, although in the embodiment, the plastic frame 31 and the metal frame 32 are fixed to each other by screws, the fixing means is not limited to the screws. Nails, adhesive, etc., can be used as well as the screws.

Referring then to FIG. 6, a description will be now given to an exemplary connection method of connecting the plastic frame 31 to the metal frame 32.

FIG. 6 is a view useful in explaining an example of a method for connecting a plastic frame 66 to a metal frame 67. FIG. 6 shows special screws 61, washers 62, screw holes 63, ellipsoidal screw holes 64, insertion portions 65, the plastic frame 66, and the metal plate 67.

In the case of FIG. 6, the special screws 61 are used to fix the plastic frame 66 to the metal plate 67, and the ellipsoidal screw holes 64 used for securing the plates are formed in the plastic frame 66. The ellipsoidal screw holes 64 are longer than a general circular hole, and hence can absorb thermal deformation of the plastic frame 66. However, for securing the plates, it is necessary to employ the special screws 61 of a particular shape each having the washer 62 that can cover the entire ellipsoidal hole 64. In other words, standard screws cannot achieve reliable fixing. Further, since the special screws 61 have a high degree of freedom along the longitudinal direction of the ellipsoidal holes 64, rigid positioning cannot be realized along the major axis. To cover this, it is necessary to form, in the plastic frame 66, other screw holes dedicated to positioning.

The TV set of the embodiment is free from this problem, and hence can reduce displacement between the plastic frame 31 and the metal frame 32.

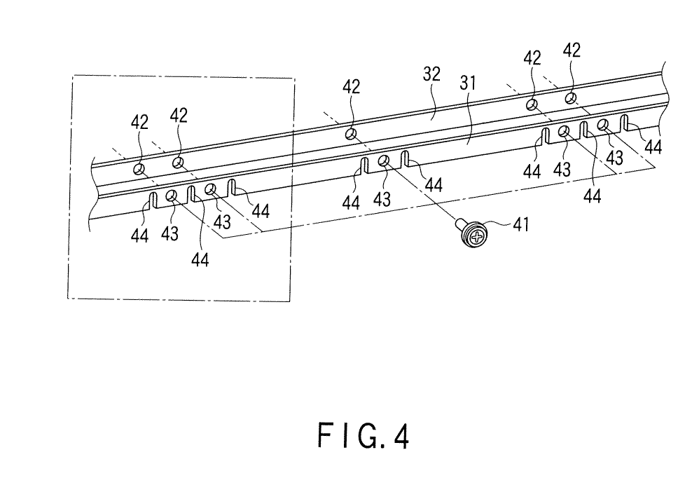

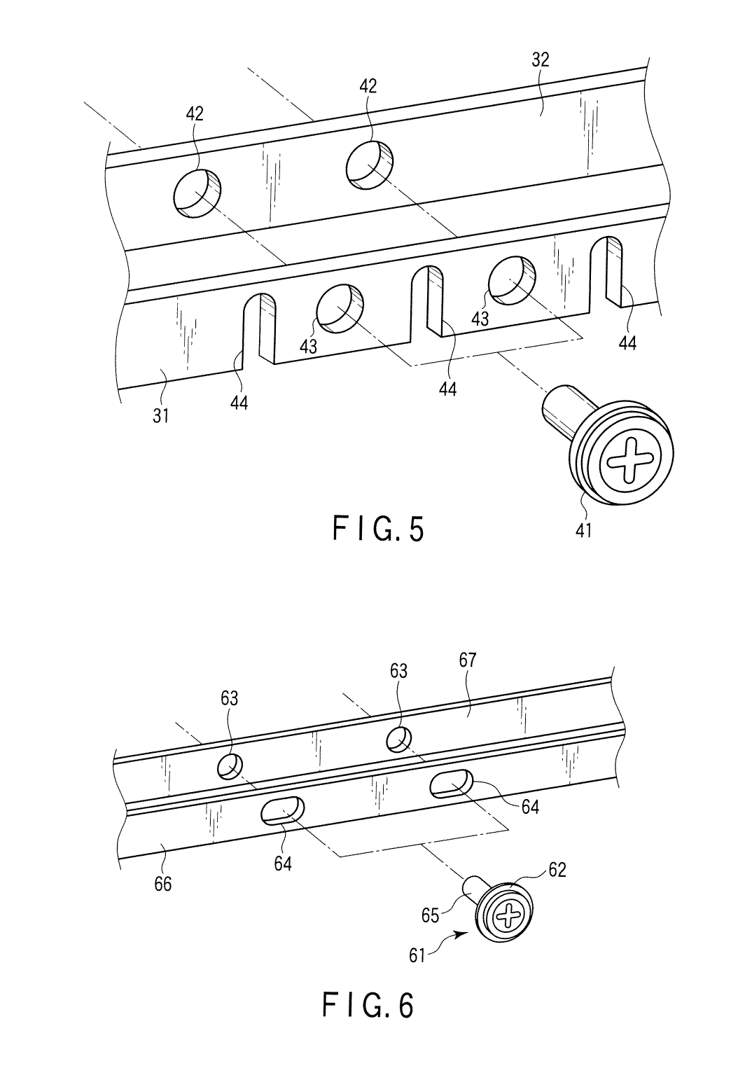

Referring to FIGS. 4 and 5, an example of a connection method employed in the embodiment will be described.

FIG. 4 is a view useful in explaining an example of a method employed in the embodiment for connecting the plastic frame 31 to the metal frame 32. FIG. 4 shows the plastic frame 31, the metal frame 32, screws 41, screw holes 42, screw holes 43 and notches 44.

Assume that in the embodiment, the screws 41 are not special ones, but standard ones. The washers of the screws 41 have a standard size. Further, the screw holes 43 and 42 formed in the plastic frame 31 and the metal frame 32, respectively, are also standard circular screw holes. The plastic frame 31 and the metal frame 32 are fixed to each other by inserting the screws 41 through the screw holes 43 and 42. The screw holes 43 are provided as fixing portions in the plastic frame 31 for fixing the frame 31 to another member.

Furthermore, in the embodiment, the notches 44 in the plastic frame 31 are formed by cutting parts of the inner periphery of the plastic frame 31. Although in the embodiment, the notches 44 are formed along the inner periphery of the plastic frame 31, holes may be formed in place of the notches. Even if the holes are formed in place of the notches 44, they can absorb thermal deformation of the frames. However, the notches have a greater deformation absorbing effect than the holes, and are therefore more suitable than the holes. The notches 44 are formed with each screw hole 43 interposed therebetween, and at least one notch 44 is formed between adjacent ones of the screw holes 43. The notches 44 formed in the plastic frame 31 can absorb deformation of the plastic frame 31 caused by changes in temperature, thereby minimizing displacement of the plastic frame 31 and the metal frame 32. Further, in the embodiment, since standard screws are used for securing the frames, such screws of a particular shape as the special screws 61 are not required. In addition, since the screw holes 43 are also standard circular screws, they have no degree of freedom in position, and hence it is not necessary to form positioning screw holes in the plastic frame 31 and the metal frame 32. Namely, without such positioning screw holes and screws inserted therethrough, the plastic frame 31 and the metal frame 32 can be positioned accurately.

The linear expansion of a member due to thermal expansion is determined from the product of the coefficient of thermal expansion of the member, the length of the member, and an increase in temperature. Assuming that the coefficient of thermal expansion of the member is α, the length of the member is L, and the increase in temperature is [symbol] T, the length [symbol] L of the extended portion of the member is given by

[symbol]

L=α×L× [symbol] T

Accordingly, if the distance between adjacent screw holes 43 is short (if L is short), the extension of the member is small, and hence only one notch 44 can sufficiently absorb deformation of the member due to a change in temperature. In contrast, if the distance is long (if L is long), two or more notches 44 can absorb great deformation of the member. Note that the greater the number of notches 44, the higher the deformation absorption effect, whereas the smaller the number of notches 44, the higher the rigidity of the plastic frame 31. In light of this, the number of notches 44 should be set to a necessary minimum value that enables deformation due to a change in temperature to be absorbed.

To determine an appropriate number of notches, some threshold values may be used. In this case, for example, if the interval between adjacent screw holes 43 is less than a first threshold value, one notch 44 is formed. If the interval between adjacent screw holes 43 is less than a second threshold value that is higher than the first threshold value, two notches 44 are formed. Similarly, if the interval between adjacent screw holes 43 is less than a third threshold value that is higher than the second threshold value, three notches 44 are formed. Thus, the number of notches 44 provided between adjacent screw holes 43 may be determined in accordance with the distance therebetween.

In the embodiment, the notches 44 are formed perpendicular to the edge of the plastic frame 31. It is convenient if each notch 44 has as a great length as possible in the area ranging from the inner edge of the plastic frame 31 to the outer edge of the same. This is because if so, thermal deformation can be absorbed over a wide area along the length. Further, the effect of the notch 44 absorbing the thermal deformation of the plastic frame 31 is increased in accordance with an increase in the width of the notch 44. For instance, if the notch 44 extends obliquely from the inner edge of the plastic frame 31, the notch 44 inevitably has a larger volume than when it extends perpendicular to the inner edge, in order to obtain the same thermal deformation absorption effect. Accordingly, the obliquely extending notch 44 will reduce the rigidity of the plastic frame 31, compared to the vertically extending notch 44. This being so, the embodiment employs the vertically extending notch 44 to maximize the thermal deformation absorption effect and minimize the reduction of the rigidity of the plastic frame 31.

Although in the embodiment, the notches 44 are formed in the plastic frame 31, the invention is not limited to this. They may be formed in the metal frame 32, or in both the plastic frame 31 and the metal frame 32. However, when the notches 44 are formed in either the plastic frame 31 or the metal frame 32, it is preferable that the notches 44 are formed in the plastic frame 31 since the plastic frame 31, which has a higher coefficient of thermal expansion than the metal frame 32, will be more greatly deformed than the metal frame 32 in accordance with a change in temperature.

FIG. 5 also shows the method employed in the embodiment for connecting the plastic frame 31 to the metal frame 32. Specifically, FIG. 5 is an enlarged view illustrating the part of FIG. 4 surrounded by the one-dot chain line.

Assume here that the plastic frame 31 and the metal frame 32 are fixed to each other by the screws 41 without any notches 44, and that the temperatures of these frames have increased. When there is an increase in temperature, the plastic frame 31 is greatly expanded to cause stress in the screws 41 and in the portions of the plastic frame 31 around the screw holes 43. As a result, a crack may occur around each screw hole 43, or the plastic frame may be significantly affected and worn by the friction between the screws 41 and the screw holes 43, whereby the resistances of the screws 41 and the plastic frame 31 may be reduced. In contrast, in the embodiment, since the notches 44 are formed in the plastic frame 31 to sandwich the screw holes 43, they absorb deformation due to an increase in temperature, thereby preventing significant concentration of stress in the screws 41 and in the portions around the screw holes 43 to thereby prevent the above-mentioned problems.

Further, in the embodiment, the notches 44 are formed in the plastic frame 31 such that they open along the inner periphery of the frame 31 and extend toward the outer periphery of the same. Since the notches 44 are thus formed, they are prevented from being exposed to the outside, when the TV set 10 is assembled and the outer periphery of the plastic frame 31 is exposed to the outside. This structure is just an example in the embodiment, therefore, this structure is not limited to it. However, when the plastic frame 31 is exposed to the outside, misalignment of the plastic frame 31 and the metal frame 32 can be suppressed without degrading the appearance of the TV set 10, by providing notches 44 along the inner periphery of the plastic frame 31.

Since the plastic frame 31 of the embodiment has a frame shape, even if a certain number of notches 44 are formed therein, the entire frame can have a sufficient strength.

In the TV set 10 of the embodiment, when members having different thermal expansion coefficients are attached to each other at a number of points, displacement of the members due to their thermal deformation can be minimized.

The invention is not limited to the above-described embodiment, but may be modified in various ways without departing from the scope. Various inventions can be realized by appropriately combining the structural elements disclosed in the embodiments. For instance, some of the disclosed structural elements may be deleted. Some structural elements of different embodiments may be combined appropriately.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A display device comprising:
a display unit including a display screen which displays images;
a first frame body formed in a frame and surrounding the display screen; and
a second frame body formed in a frame, having substantially a same size as the first frame body, and formed of a material having a higher coefficient of thermal expansion than the first frame body, the second frame body being fixed to the first frame body using a plurality of fixing portions, the second frame body with notches provided between the fixing portions.

2. The display device of claim 1, wherein the second frame body has a portion exposed to an outside of the display device, and the notches open along an inner periphery of the second frame body and extend toward the outer periphery of the second frame body.

3. The display device of claim 1, wherein when a distance between adjacent ones of the fixing portions of the second frame body is greater than a preset value, two or more of the notches are formed between the adjacent fixing portions.

4. The display device of claim 1, wherein the notches extend from an inner periphery of the second frame body perpendicularly with respect to the inner periphery.

5. The display device of claim 1, further comprising a tuner which receives broadcasting waves, and wherein the display unit displays, on the display screen, images corresponding to the broadcasting waves received by the tuner.

6. A frame body for a display device provided with a display screen which displays images, the frame body being formed in a frame and surrounding the display screen, comprising:
a plurality of fixing portions to be fixed to another member; and
wherein the frame body is provided with notch between the plurality of fixing portions.
